(19) United States
(12) Patent Application Publication
(10) Pub. No.: US 2025/0383494 A1
(43) Pub. Date: Dec. 18, 2025

(54) LIGHT BEAD, LIGHT PLATE, AND DISPLAY DEVICE

(71) Applicant: HKC Corporation Limited, Shenzhen (CN)

(72) Inventors: HONGSONG WANG, Shenzhen (CN); Pei Xu, Shenzhen (CN)

(21) Appl. No.: 19/234,271

(22) Filed: Jun. 11, 2025

(30) Foreign Application Priority Data
Jun. 13, 2024 (CN) 202410758737.3

(51) Int. Cl. F21V 8/00

(52) U.S. Cl. CPC G02B 6/0073; G02B 6/0068; G02B 6/0085

(57) ABSTRACT

A light bead, a light plate, and a display device are disclosed. The light bead includes a light-emitting chip disposed at a bottom of the light bead, a light diffusing and collimating assembly disposed on a light-exiting side of the light-emitting chip, and a light-exiting layer. The light-exiting layer includes a first, a second, and a third light-emitting region, and two baffles. When the light-emitting chip is in operation, the emitted light passes through the light diffusing and collimating assembly and enters each of the first, the second, and the third light-emitting region, thus forming a first color light after passing through the first light-emitting region, a second color light after passing through the second light-emitting region, and not changing the color of the light after passing through the third light-emitting region, so that the light bead is able to emit light in three different colors.

### CROSS-REFERENCE TO RELATED APPLICATIONS

This application claims the priority and benefit of Chinese patent application number 2024107587373, titled “Light Bead, Light Plate, and Display Device” and filed Jun. 13, 2024 with China National Intellectual Property Administration, the entire contents of which are incorporated herein by reference.

### TECHNICAL FIELD

The present application relates to the field of light bead mass transfer technology, and more particularly relates to a light bead, a light plate, and a display device.

### BACKGROUND

The description provided in this section is intended for the mere purpose of providing background information related to the present application but does not necessarily constitute prior art.

With the innovation and development of LED (light-emitting diode) technology, Micro-LED (Micro Light-Emitting Diode Display) technology has become the next-generation display technology. It involves miniaturizing and matrixing the LED structure, reducing the size of each individual LED chip to tens of micrometers or even a few micrometers, and achieving the addressing and individual driving of each LED pixel to emit light. Since Micro-LED chip displays have the advantages of high resolution, high brightness, long lifespan, wide operating temperature range, strong anti-interference capability, fast response speed, and low power consumption etc., Micro-LED holds significant application values in fields including high-resolution displays, helmet-mounted displays, augmented reality, high-speed visible light communication, micro projectors, optogenetics, wearable electronics, and so on.

A full-color gamut LED display screen is assembled by arranging red, green, and blue (three primary colors of RGB) Micro-LED chips on a substrate in a specific pattern. In related RGB configurations, each group consists of three chips namely red, green, and blue chips that are spaced apart from each other with uniform spacing on a horizontal plane to achieve the RGB color effect. However, the size of each RGB group is relatively large, and the assembly process is complex, requiring sequential arrangement of the red, green, and blue chips. As a result, a large number of chips need to be mass-transferred during the mass transfer process, thus placing high requirements on the Micro-LED mass transfer process and leading to a relatively low yield in mass production.

### SUMMARY

One objective of the present application is therefore to provide a light bead, a light plate, and a display device. By configuring the structure of the light bead, the requirements on the mass transfer process are reduced, thereby improving the production yield of the Micro-LED display screen using the light-emitting chip.

The present application discloses a light bead, which is applied to a light plate. The light bead includes a light-emitting chip, a light diffusing and collimating assembly, and a light-exiting layer. The light-emitting chip is disposed at a bottom of the light bead. The light diffusing and collimating assembly is arranged on a light-exiting side of the light-emitting chip, and is configured to diffuse the light rays emitted from the light-emitting chip and adjust the light rays to be emitted at mutually parallel angles. The light-exiting layer includes a first light-emitting region, a second light-emitting region, a third light-emitting region, and two baffles. One of the two baffles is disposed between the first light-emitting region and the second light-emitting region, and the other baffle is disposed between the second light-emitting region and the third light-emitting region. The first light-emitting region includes a first color phosphor and a first color film. The second light-emitting region includes a second color phosphor and a second color film. The third light-emitting region includes a transparent film. The light-emitting chip is disposed corresponding to a central portion of the light-exiting layer. When the light-emitting chip is in operation, the emitted light passes through the light diffusing and collimating assembly and enters each of the first light-emitting region, the second light-emitting region, and the third light-emitting region. After passing through the first light-emitting region, the light forms a first color light; after passing through the second light-emitting region, the light forms a second color light; after passing through the third light-emitting region, the light color remains unchanged, such that the light bead emits light of three different colors.

In some embodiments, the light diffusion and collimating assembly includes a diffusion plate, a convex lens, and a planarization layer. The diffusion plate is disposed adjacent to the light-exiting side of the light-emitting chip. The convex lens is disposed on the side of the diffusion plate that faces away from the light-emitting chip. The planarization layer is disposed on an edge region of the convex lens, such that the side of the light diffusing and collimating assembly facing the light-exiting layer forms a flat surface. When the light-emitting chip is in operation, light passes through the diffusion plate to increase the emitting angle of the light, so that the light is directed into various regions of the convex lens. Under the action of the convex lens and the planarization layer, the light is adjusted to be perpendicular to a light-exiting surface of the light bead, and then enters the light-exiting layer.

In some embodiments, the light emitted by the light-emitting chip is blue light. The first color phosphor is a red phosphor. The first color film is a red color film. The second color phosphor is a green phosphor. The second color film is a green color film.

Alternatively, the first color phosphor is a green phosphor. The first color film is a green color film. The second color phosphor is a red phosphor. The second color film is a red color film.

In some embodiments, the light bead further includes a reflective layer disposed on a side of the light-emitting chip facing away from the light diffusing and collimating assembly, and configured to reflect the light emitted by the light-emitting chip.

In some embodiments, the light bead further includes a second positioning piece disposed on the side of the reflective layer facing away from the light-emitting chip. The second positioning piece is a magnetic positioning piece.

The present application further discloses a light plate, which is applied to a display device. The light plate includes a bottom plate, a partition plate, a plurality of flow guiding assemblies, and a plurality of light beads as described above. An airflow channel is disposed on the bottom plate. The airflow channel includes a plurality of ventilation holes and a main airflow channel. Each of the plurality of ventilation holes communicates with the main airflow channel. The partition plate is spaced apart from the bottom plate. The partition plate is divided into a plurality of sections. The number of the plurality of sections is equal to the number of the plurality of ventilation holes. Each section includes a respective ventilation hole. The main airflow channel is disposed between the partition plate and the bottom plate. An airflow enters from the main airflow channel and is discharged along the plurality of ventilation holes. The plurality of flow guiding assemblies are disposed on the partition plate and are arranged in one-to-one correspondence on the plurality of sections. Each flow guiding assembly includes a flow guiding channel connected to the corresponding ventilation hole. The flow guiding channel includes a first branch flow channel and a second branch flow channel. An air inlet end of the first branch flow channel and an air inlet end of the second branch flow channel each communicate with the corresponding ventilation hole. An air outlet end of the first branch flow channel and an air outlet end of the second branch flow channel are each disposed on the side of the corresponding flow guiding assembly facing away from the partition plate, and are spaced apart from each other. A first positioning piece is disposed on the side of each flow guiding assembly facing away from the partition plate.

The plurality of light beads are disposed in one-to-one correspondence on the plurality of flow guiding assemblies. Each light bead includes a second positioning piece that is configured to be engaged with the corresponding first positioning piece. The first positioning piece and the second positioning piece are configured to be engaged with each other to fix each respective light bead to the corresponding flow guiding assembly. When the plurality of light beads are laid on the plurality of flow guiding assemblies, air is introduced into the main airflow channel, and the airflow alternately passes through the first branch flow channel and the second branch flow channel and is discharged, thereby lifting the corresponding light bead on each flow guiding assembly. This allows each light bead to gradually adjust its position on the corresponding flow guiding assembly until the first positioning piece and the second positioning piece are engaged with each other to complete the installation of the light bead.

In some embodiments, the light plate further includes a displacement assembly, which is disposed at an edge region of the bottom plate. The displacement assembly includes a first retaining wall, a second retaining wall, and a blocking structure. The second retaining wall is disposed adjacent to the plurality of flow guiding assemblies. The first retaining wall and the second retaining wall are spaced apart to jointly define an accommodating space. A first through hole is defined in the second retaining wall, and communicates with the main airflow channel so as to allow an airflow to enter the accommodating space. The blocking structure is disposed inside the accommodating space. The blocking structure includes a first end adjacent to the bottom plate and a second end facing away from the bottom plate. A sealing piece is disposed on the first end of the blocking structure. The first end of the blocking structure abuts against the first retaining wall and the second retaining wall, so that a gas storage space is formed between the first end of the blocking structure and the bottom plate. The first through hole communicates with the gas storage space. A suction piece is disposed on the second end of the blocking structure and is configured to suction a glass cover plate in the display device. When the plurality of light beads are laid on the plurality of flow guiding assemblies, air is introduced into the main airflow channel, and the airflow enters the gas storage space through the first through hole, thereby pushing the blocking structure to move toward the side facing away from the bottom plate, so as to prevent the light beads from jumping out of the light plate.

In some embodiments, the displacement assembly further includes a restoration structure, which includes a first fixing piece and a first elastic piece. Two first fixing pieces are provided and respectively disposed on the first retaining wall and the second retaining wall. Two first elastic pieces are also provided, each disposed corresponding to a respective one of the two first fixing pieces. The second end of the blocking structure extends between the two first fixing pieces. The blocking structure further includes an abutting portion configured to abut against each of the two first elastic pieces. One end of each first elastic piece is fixedly connected to the corresponding first fixing piece, and the other end is connected to the corresponding abutting portion of the blocking structure. When air is introduced into the main airflow channel, the airflow enters the gas storage space through the first through hole, pushing the blocking structure to move away from the bottom plate, so that each first elastic piece is compressed and deformed to store energy. When the airflow into the main airflow channel stops, each first elastic piece releases its stored potential energy to push the blocking structure to move back toward the bottom plate.

In some embodiments, each of the first elastic pieces is a compression spring.

This application further discloses a display device, where the display device includes a driving circuit and the light plate as described above. The driving circuit is configured to drive the light plate to emit light.

Compared with the related RGB light bead solution, where three chips (red, green, and blue) are spaced apart and arranged evenly on the horizontal plane to achieve the RGB effect, the light bead in this embodiment, when installed onto a Micro-LED display screen, is capable of emitting light in all three primary colors from a single light bead. This reduces the number of light beads required to be installed in the mass transfer process, thereby lowering the requirements on the mass transfer process and improving the production yield of the Micro-LED display screen. It also reduces the assembly difficulty, making the production of the Micro-LED display screen more efficient.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative efforts. In the drawings:

FIG. 1 is a schematic diagram of a light bead according to a first embodiment of the present application.

FIG. 2 is a schematic diagram of a light plate according to a second embodiment of the present application.

FIG. 3 is an enlarged view of portion A shown in FIG. 2 according to this application.

FIG. 4 is an enlarged view of portion B shown in FIG. 2 according to this application.

FIG. 5 is a schematic diagram of a light plate according to the second embodiment of the present application in which light beads are laid prior to installation.

FIG. 6 is a schematic diagram of a light plate with all light beads installed according to the second embodiment of the present application.

FIG. 7 is a schematic diagram of a glass cover plate being prepared to be installed on a light plate according to the second embodiment of the present application.

FIG. 8 is a schematic diagram of a light plate after the glass substrate is installed according to the second embodiment of the present application.

FIG. 9 is a flowchart of a method of assembling a light plate according to a third embodiment of the present application.

FIG. 10 is a schematic diagram of a display device according to a fourth embodiment of the present application.

In the drawings: 100, light plate; 110, bottom plate; 111, circuit board; 112, air barrier layer; 120, airflow channel; 121, ventilation hole; 122, main airflow channel; 130, partition plate; 140, flow guiding assembly; 141, first positioning piece; 142, main body; 142a, first cavity; 143, rotating shaft; 144, pulse swinging piece; 144a, rotating end; 144b, swinging end; 145, elastic recovery piece; 150, flow guiding channel; 151, first branch flow channel; 152, second branch flow channel; 200, light bead; 210, second positioning piece; 220, light-emitting chip; 230, light diffusing and collimating assembly; 231, diffusion plate; 232, convex lens; 233, planarization layer; 240, light-exiting layer; 241, first light-emitting region; 242, second light-emitting region; 243, third light-emitting region; 244, baffle; 250, reflective layer; 300, displacement assembly; 310, first retaining wall; 320, second retaining wall; 321, first through hole; 340, blocking structure; 341, sealing piece; 342, gas storage space; 343, suction piece; 344, abutting portion; 350, restoration structure; 351, first fixing piece; 352, first elastic piece; 400, glass cover plate; 500, driving circuit; 600, display device.

### DETAILED DESCRIPTION OF EMBODIMENTS

It should be understood that the terms used herein, the specific structures arrangements, and the functional details disclosed herein are merely representative for describing some specific embodiments, but the present application may be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Terms “comprise”, “comprising”, “includes”, “including”, and any variations thereof are intended to be non-exclusive, and one or more other features, integers, steps, operations, units, components, and/or combinations thereof may be present or be added.

In addition, terms “center” “lateral”, “up”, “down”, “left”, “right”, “vertical”, and “horizontal”, “top”, “bottom”, “inside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

In addition, unless otherwise clearly specified and defined, the terms “installed on”, “mounted on”, “disposed on”, “arranged on”, “coupled to”, and “connected to” should be understood in a broad sense. For example, it may be a fixed connection, a detachable connection, or an integral connection; it may be a mechanical connection or an electrical connection; it may be a direct connection or an indirect connection through an intermediate medium, or it may also be internal communication between two elements. For those of ordinary skill in the art, the specific meanings of the above terms as used in the present application can be understood depending on specific contexts.

As used herein, the term “emitting angle” refers to the angular range within which light exits from a surface, layer, or optical element, regardless of whether the surface itself is a light-emitting source. The emitting angle characterizes the directional distribution of light output and is commonly used to describe how light is diffused, directed, or shaped by optical structures such as light guide plates, diffusers, or lenses. In this context, “emitting angle” is analogous to “viewing angle” and serves to indicate the effective angle over which light can be observed or utilized after passing through or being redirected by an optical component.

The present application is described in detail below with reference to the accompanying drawings and optional embodiments. It should be noted that, under the premise of no conflict, the embodiments or technical features described below can be arbitrarily combined to form new embodiments.

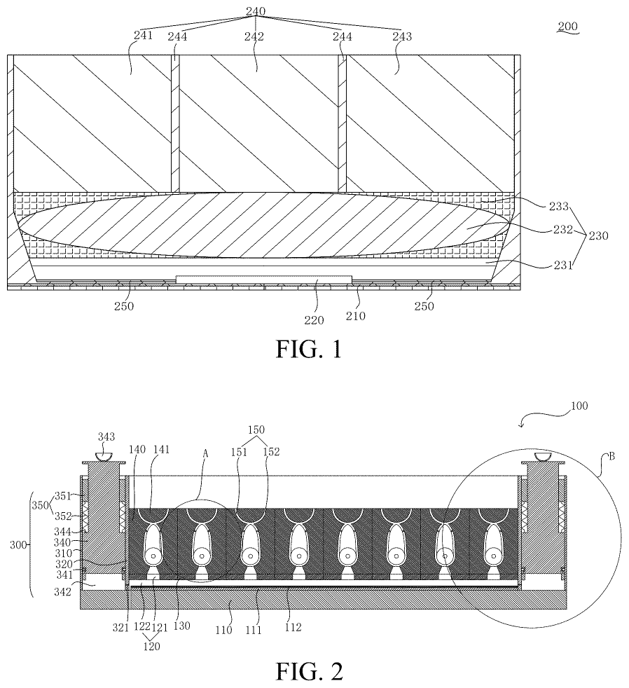

As shown in FIG. 1, as a first embodiment of the present application, a light bead 200 is disclosed. Also referring to FIG. 2, the light bead 200 is applied to a light plate 100. The light bead 200 includes a light-emitting chip 220, a light diffusing and collimating assembly 230, and a light-exiting layer 240. The light-emitting chip 220 is disposed at a bottom of the light bead 200. The light diffusing and collimating assembly 230 is disposed on a light-exiting side of the light-emitting chip 220. The light diffusing and collimating assembly 230 is configured to diffuse the light emitted by the light-emitting chip 220 and collimate it into parallel rays for emission. The light-exiting layer 240 includes a first light-emitting region 241, a second light-emitting region 242, a third light-emitting region 243, and two baffles 244. One of the two baffles 244 is disposed between the first light-emitting region 241 and the second light-emitting region 242, and the other baffle 244 is disposed between the second light-emitting region 242 and the third light-emitting region 243, thus separating the first light-emitting region 241, the second light-emitting region 242, and the third light-emitting region 243 from one another. The first light-emitting region 241 includes a first color phosphor and a first color film. The second light-emitting region 242 includes a second color phosphor and a second color film. The third light-emitting region 243 includes a transparent film. The light-emitting chip 220 is disposed corresponding to a central portion of the light-exiting layer 240. When the light-emitting chip 220 is in operation, light emitted therefrom passes through the light diffusing and collimating assembly 230 and is directed into each of the first light-emitting region 241, the second light-emitting region 242, and the third light-emitting region 243. After passing through the first light-emitting region 241, the light forms a first color light; after passing through the second light-emitting region 242, the light forms a second color light; and after passing through the third light-emitting region 243, the light remains unchanged in color, thereby enabling the light bead 200 to emit light in three different colors.

In this embodiment, the light bead 200 includes a light diffusing and collimating assembly 230 and a light-exiting layer 240. The light diffusing and collimating assembly 230 is capable of diffusing the light emitted by the light-emitting chip 220 and adjusting it to be parallel rays before entering the light-exiting layer 240. Then, through the first light-emitting region 241, the second light-emitting region 242, the third light-emitting region 243, and the baffles 244 included in the light-exiting layer 240, the light emitted from the light bead 200 can form three colors, that is, form three-primary-color light. Therefore, when the light bead 200 of this embodiment is applied to a Micro-LED display screen, compared with the related RGB light beads which require three separate chips-red, green, and blue-arranged evenly and spaced apart on the horizontal plane to achieve the RGB effect, the light bead 200 of this embodiment, since one light bead 200 can emit light in three primary colors, reduces the number of light beads 200 required to be mounted in the mass transfer process when it is installed on a Micro-LED display screen, thereby lowering the requirements on the mass transfer process, improving the production yield of the Micro-LED display screen, and also reducing the assembly difficulty, which facilitates the production of the Micro-LED display screen. It should be noted that, in this embodiment, the light emitted by the light-emitting chip 220 may be blue light. The first color phosphor may be red phosphor, the first color film may be a red color film, the second color phosphor may be a green phosphor, and the second color film may be a green color film. When the light emitted by the light-emitting chip 220 enters the first light-emitting region 241, it provides a light source for the first color phosphor included in the first light-emitting region 241, causing the first color phosphor to emit red light after absorbing the light. Then it passes through the first color film, so that the light that can be emitted from the first light-emitting region 241 is only red light. When the light emitted by the light-emitting chip 220 enters the second light-emitting region 242, it provides a light source for the second color phosphor included in the second light-emitting region 242, causing the second color phosphor to emit green light after absorbing the light. Then it passes through the second color film, so that the light that can be emitted from the second light-emitting region 242 is only green light, thereby enabling the light bead 200 to provide three-primary-color light. Of course, the first color phosphor, the first color film, the second color phosphor, and the second color film are not to be limited to the colors described above. The first color phosphor may also be configured as a green phosphor, the first color film as a green color film, the second color phosphor as a red phosphor, and the second color film as a red color film. Designers may select the colors used according to actual needs, and no further elaboration is to be provided here for the purpose of brevity.

As further shown in FIG. 1, the light diffusing and collimating assembly 230 includes a diffusion plate 231, a convex lens 232, and a planarization layer 233. The diffusion plate 231 is disposed adjacent to the light-exiting side of the light-emitting chip 220. The convex lens 232 is disposed on the side of the diffusion plate 231 that faces away from the light-emitting chip 220. The planarization layer 233 is disposed on an edge region of the convex lens 232, so that the side of the light diffusing and collimating assembly 230 adjacent to the light-exiting layer 240 becomes a flat surface. When the light-emitting chip 220 is in operation, the light passes through the diffusion plate 231 to expand the emitting angle of the light, so that the light enters various regions of the convex lens 232. Under the action of the convex lens 232, the light is further dispersed, and then, under the action of the planarization layer 233, the light is corrected to be perpendicular to the light-exiting surface of the light bead 200, and then enters the light-exiting layer 240. In this embodiment, the position of the light-emitting chip 220 may correspond to a central portion of the light-exiting layer 240, so that the light emitted from the light-emitting chip 220 can enter the diffusion plate 231 at a better angle for diffusion, thereby enabling the light to be more evenly distributed into the first light-emitting region, the second light-emitting region, and the third light-emitting region.

Furthermore, in order to improve the utilization rate of the light, in this embodiment, as shown in FIG. 1, the light bead 200 further includes a reflective layer 250, which is disposed on the side of the light-emitting chip 220 facing away from the light diffusing and collimating assembly 230. The reflective layer 250 is used to reflect the light emitted from the light-emitting chip 220, so that the light originally emitted in other directions by the light-emitting chip 220 or the light reflected back by the diffusion plate 231 can be reflected by the reflective layer 250 and then enter the light diffusing and collimating assembly 230 for utilization, thereby improving the utilization rate of the light to a certain extent.

As shown in FIG. 1, the light plate 100 further includes a second positioning piece 210, which is disposed on the side of the reflective layer 250 facing away from the light-emitting chip 220. The second positioning piece 210 may be implemented as a magnetic piece. In this embodiment, the magnetic positioning piece may be an electromagnet. The second positioning piece 210 on the light bead 200 may be energized to generate magnetism for magnetic attraction and engagement with the first positioning piece 141 on the light plate 100. A wireless coil may be disposed on the light plate 100 to supply power.

As shown in FIGS. 2 to 4, as a second embodiment of the present application, a light plate 100 is disclosed, which is applied to a display device. The light plate 100 includes a bottom plate 110, a partition plate 130, a plurality of flow guiding assemblies 140, and a plurality of light beads 200 as described in the above embodiment. An airflow channel 120 is disposed on the bottom plate 110. The airflow channel 120 includes a plurality of ventilation holes 121 and a main airflow channel 122. The plurality of ventilation holes 121 communicate with the main airflow channel 122. The partition plate 130 is disposed to be spaced apart from the bottom plate 110. The partition plate 130 is divided into a plurality of sections, the number of which is equal to the number of the ventilation holes 121. Each of the sections includes a corresponding ventilation hole 121. The main airflow channel 122 is disposed between the partition plate 130 and the bottom plate 110. After the airflow enters from the main airflow channel 122, it is discharged through the plurality of ventilation holes 121. The plurality of flow guiding assemblies 140 are disposed on the partition plate 130, and are respectively arranged on the plurality of sections in one-to-one correspondence. Each flow guiding assembly 140 includes a flow guiding channel 150 connected to the corresponding ventilation hole 121. The flow guiding channel 150 includes a first branch flow channel 151 and a second branch flow channel 152. An air inlet end of the first branch flow channel 151 and an air inlet end of the second branch flow channel 152 each communicate with the corresponding ventilation hole 121. An air outlet end of the first branch flow channel 151 and an air outlet end of the second branch flow channel 152 are disposed on the side of the corresponding flow guiding assembly 140 facing away from the partition plate 130, and are spaced apart from each other. A first positioning piece 141 is disposed on a side of each flow guiding assembly 140 facing away from the partition plate 130. The plurality of light beads 200 are respectively disposed on the plurality of flow guiding assembly 140 in one-to-one correspondence. Each of the light beads 200 includes a second positioning piece 210 configured to be engaged with the corresponding first positioning piece 141 (referred to FIG. 1). The first positioning piece 141 is configured to be engaged with the second positioning piece 210 to mount each light bead 200 onto the corresponding flow guiding assembly 140. When the light beads 200 are laid onto the flow guiding assemblies 140, air is introduced into the main airflow channel 122 so that the airflow is alternately discharged through the first branch flow channel 151 and the second branch flow channel 152, thereby lifting the light bead 200 located on the flow guiding assembly 140, so that the light bead 200 gradually adjusts its position on the flow guiding assembly 140 until the first positioning piece 141 and the second positioning piece 210 are engaged to achieve the installation of the light bead 200.

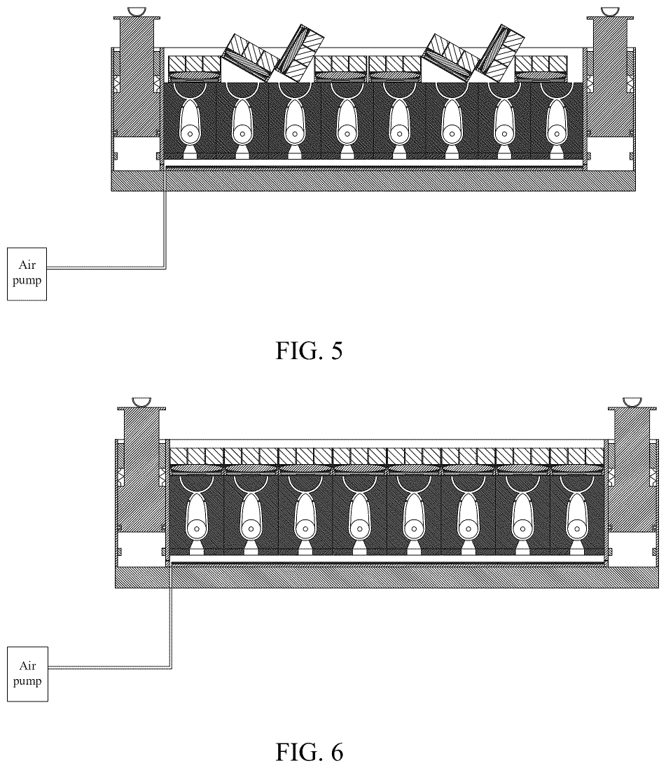

When installing the light beads 200 on the light plate 100, the light beads 200 may first be laid on the flow guiding assemblies 140, as shown in FIG. 5. At this time, the light beads 200 are arranged disorderly above the flow guiding assemblies 140. Then, the air pump is started to operate, and the airflow enters from the main airflow channel 122, passes through each ventilation hole 121, and then enters the flow guiding channel 150 in the corresponding flow guiding assembly 140. The airflow is then alternately discharged from the air outlet end of the first branch flow channel 151 and the air outlet end of the second branch flow channel 152, thereby lifting the corresponding light bead 200 located on the flow guiding assembly 140 so that the light bead 200 gradually adjusts its position on the flow guiding assembly 140 until the second positioning piece 210 on the light bead 200 is engaged with the first positioning piece on the flow guiding assembly 140 thus achieving the installation of the light bead 200. After installation, the light bead 200 would not be lifted by the air discharged from the first branch flow channel 151 and the second branch flow channel 152 due to the engagement between the first positioning piece 141 and the second positioning piece 210. It will be fixed onto the flow guiding assembly 140 to wait for the remaining light beads 200 to be installed. After the installation of all the light beads 200 is completed, the air pump is turned off. As shown in FIG. 6, it shows the light plate 100 after all the light beads 200 are installed, so as to proceed to the next step of installation of the light plate 100. According to the light plate 100 of this embodiment, the corresponding light bead 200 is lifted up through the structure of the flow guiding channel 150 in each flow guiding assembly 140, so that the light bead 200 gradually adjusts its position on the flow guiding assembly 140, thereby realizing the installation of the light bead 200. Compared with the related installation process of a Micro-LED display screen, it reduces the requirements on the mass transfer process in manufacturing the Micro-LED display screen, improves the installation efficiency and accuracy of the light beads 200, thus leading to a superior application prospect. It should be noted that in this embodiment, the first positioning piece 141 and the second positioning piece 210 may be magnetic pieces, and the first positioning piece 141 and the second positioning piece 210 are magnetically connected so as to be engaged with each other. The second positioning piece 210 disposed on the light bead 200 may be an electromagnet so that when the light bead 200 falls correctly into the position on the flow guiding assembly 140, the second positioning piece 210 of the light bead 200 may be energized to generate magnetism so as to be magnetically connected with the first positioning piece 141. A wireless coil may be disposed on the light bead 200 to conduct electricity. It is only needed to provide a power supply structure, which cooperates with the wireless coil, at the corresponding position of each section on the flow guiding assembly 140, which however is not to be described in detail herein for brevity.

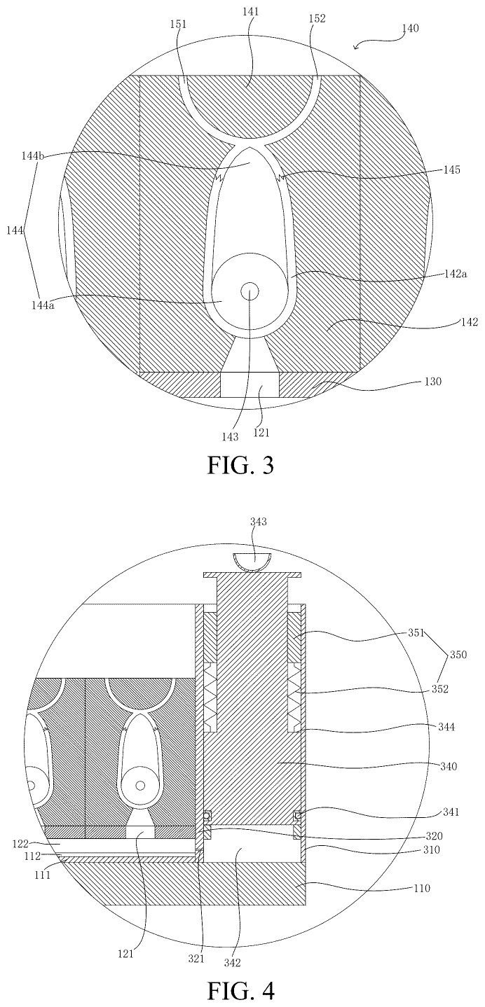

Furthermore, as shown in FIGS. 2 and 3, each flow guiding assembly 140 includes a main body 142, a rotating shaft 143, and a pulse swinging piece 144. The main body 142 is disposed on the partition plate 130. The main body 142 includes a first cavity 142a, which communicates with the flow guiding channel 150. The corresponding ventilation hole 121 is in communication with the flow guiding channel 150 through the first cavity 142a. The rotating shaft 143 and the pulse swinging piece 144 are arranged inside the first cavity 142a. The pulse swinging piece 144 includes a rotating end 144a and a swinging end 144b disposed away from the rotating end 144a. The rotating shaft 143 is rotatably connected to the rotating end 144a. When the rotating end 144a rotates, the swinging end 144b alternately comes into contact with the inner walls located on both sides of the first cavity 142a along with the rotational direction of the rotating end 144a, so that the airflow is alternately discharged from the first branch flow channel 151 and the second branch flow channel 152. Along the light-emitting direction of the light plate 100, the cross-section of the swinging end 144b of the pulse swinging piece 144 is configured as a semi-elliptical shape, and the cross-sections of the first branch flow channel 151 and the second branch flow channel 152 are each configured as an arc shape. The first branch flow channel 151 and the second branch flow channel 152 may be combined to form a semicircular arc shape. Furthermore, along the light-emitting direction of the light plate 100, the curvature of the cross-section of the swinging end 144b is greater than the curvature of the cross-section of each of the first branch flow channel 151 and the second branch flow channel 152.

When the light bead 200 is being installed, after the airflow in the main airflow channel 122 passes through the ventilation hole 121 and enters the flow guiding channel 150, the pulse swinging piece 144 begins to move. Specifically, the rotating end 144a of the pulse swinging piece 144 starts to rotate, causing the swinging end 144b of the pulse swinging piece 144 to alternately contact the inner walls on both sides of the first cavity 142a along the rotational direction of the rotating end 144a. This allows the airflow to be alternately discharged from the first branch flow channel 151 and the second branch flow channel 152, thereby lifting the light bead 200 located on the flow guiding assembly 140. More specifically, when the swinging end 144b of the pulse swinging piece 144 contacts the inner wall on the left side of the first cavity 142a, a channel for airflow is present on the right side of the first cavity 142a. According to the Coanda effect, the airflow at this time flows through the right side of the first cavity 142a and enters the first branch flow channel 151 along the swinging end 144b of the pulse swinging piece 144 and the contour of the right side of the first cavity 142a, and is then discharged from the air outlet end of the first branch flow channel 151, thereby lifting the light bead 200 adjacent to the first branch flow channel 151 on the flow guiding assembly 140, causing the light bead 200 to shift and adjust its position. When the swinging end 144b of the pulse swinging piece 144 contacts the inner wall on the right side of the first cavity 142a, a channel for airflow is present on the left side of the first cavity 142a. According to the Coanda effect, the airflow at this time flows through the left side of the first cavity 142a and enters the second branch flow channel 152 along the swinging end 144b of the pulse swinging piece 144 and the contour of the left side of the first cavity 142a, and is then discharged from the air outlet end of the second branch flow channel 152, thereby lifting the light bead 200 adjacent to the second branch flow channel 152 on the flow guiding assembly 140. The rotating end 144a of the pulse swinging piece continuously performs a reciprocating rotational motion, which drives the swinging end 144b of the pulse swinging piece to alternately contact the inner walls on both sides of the first cavity 142a. As a result, the airflow is alternately discharged from the first branch flow channel 151 and the second branch flow channel 152, thereby continuously lifting the light bead 200 not yet installed on the flow guiding assembly 140, to adjust the position of the light bead 200 on the flow guiding assembly 140, until the second positioning piece 210 on the light bead 200 is engaged with the first positioning piece 141 on the flow guiding assembly 140 to realize the installation of the light bead 200. It should be noted that the “left side” and “right side” of the first cavity 142a mentioned above are described based on the orientation and posture shown in FIG. 2. The usage of these directional terms is only intended for the convenience of understanding and is not meant to limit the specification to specifically the left or right side.

As shown in FIGS. 2 and 3, in order to facilitate the reciprocating swinging movement of the swinging end 144b of the pulse swinging piece 144 within the first cavity 142a, the flow guiding assembly 140 further includes an elastic recovery piece 145. There are disposed two elastic recovery pieces 145, which are respectively disposed on both sides of the swinging end 144b of the pulse swinging piece 144. One end of each elastic recovery piece 145 is connected to the swinging end 144b, and the other end is connected to a corresponding inner wall of the first cavity 142a. When the rotating end 144a of the pulse swinging piece 144 rotates, and the swinging end 144b of the pulse swinging piece 144 comes into contact with the inner wall on the left side of the first cavity 142a, the elastic recovery piece 145 located on the left side of the first cavity 142a is compressed to store energy. At this time, the airflow flows through the right side of the first cavity 142a and enters the first branch flow channel 151 for discharge, until the rotating end 144a of the pulse swinging piece 144 rotates to switch the swinging end 144b of the pulse swinging piece 144 into contact with the inner wall on the right side of the first cavity 142a. In this process, the elastic recovery piece 145 located on the left side of the first cavity 142a releases elastic potential energy, allowing the swinging end 144b of the pulse swinging piece 144 to more quickly contact the right side of the first cavity 142a. Meanwhile, the elastic recovery piece 145 located on the right side of the first cavity 142a is compressed to store energy, until the rotating end 144a of the pulse swinging piece 144 rotates again. Therefore, elastic recovery pieces 145 are respectively arranged on both sides of the pulse swinging piece 144. During the swinging motion of the swinging end 144b of the pulse swinging piece 144, the elastic recovery piece 145 on one side can instantaneously release the energy stored during the compression, thereby allowing the swinging end 144b of the pulse swinging piece 144 to swing back and forth more smoothly within the first cavity 142a, so that the airflow can be alternately discharged from the first branch flow channel 151 and the second branch flow channel 152 at a faster alternating rate. In this embodiment, each elastic recovery piece 145 is a return spring. One end of the return spring is connected to the corresponding inner wall of the first cavity 142a, and the other end is connected to the swinging end 144b of the pulse swinging piece 144.

As shown in FIGS. 2 and 4, in order to prevent the circuit board 111 inside the light plate 100 from being affected by airflow during the assembly of the light beads 200, which may lead to poor installation, the bottom plate 110 further includes a circuit board 111 and an air barrier layer 112 disposed on the circuit board 111. The circuit board 111 is electrically connected to the light beads 200 to control the light emission of the light beads 200. The air barrier layer 112 covers the circuit board 111 to prevent the airflow from affecting the circuit board 111 before it enters the ventilation holes 121 from the main airflow channel 122. The air barrier layer 112 is used to protect the circuit board 111.

As shown in FIGS. 2 and 4, the light plate 100 further includes a displacement assembly 300, which is disposed at an edge region of the bottom plate 110. The displacement assembly 300 includes a first retaining wall 310, a second retaining wall 320, and a blocking structure 340. The second retaining wall 320 is disposed adjacent to the flow guiding assemblies 140. The first retaining wall 310 and the second retaining wall 320 are spaced apart to jointly form an accommodating space. A first through hole 321 is defined in the second retaining wall 320, which communicates with the main airflow channel 122 to allow airflow to enter the accommodating space. The blocking structure 340 is disposed within the accommodating space. The blocking structure 340 includes a first end adjacent to the bottom plate 110 and a second end facing away from the bottom plate 110. A sealing piece 341 is disposed on the first end of the blocking structure 340. The first end of the blocking structure 340 abuts against both the first retaining wall 310 and the second retaining wall 320, so that a gas storage space 342 is formed between the first end of the blocking structure 340 and the bottom plate 110. The first through hole 321 communicates with the gas storage space 342. A suction piece 343 is disposed on the second end of the blocking structure 340, and is used to suction the glass cover plate 400 in the display device.

When the light beads 200 are installed on the light plate 100, the light beads 200 are laid on the flow guiding assemblies 140. At this time, air is introduced into the main airflow channel 122. The airflow enters the gas storage space 342 through the first through hole 321, thereby moving the blocking structure 340 toward the side facing away from the bottom plate 110, so as to lift the blocking structure 340 to block the light beads 200 that are lifted by the airflow discharged from the first branch flow channel 151 and the second branch flow channel 152, preventing the light beads 200 from jumping out of the light plate 100, and ensuring that the light beads 200 adjust their positions on the light plate 100.

Furthermore, the displacement assembly 300 further includes a restoration structure 350. The restoration structure 350 includes a first fixing piece 351 and a first elastic piece 352. Two first fixing pieces 351 are provided and are respectively disposed on the first retaining wall 310 and the second retaining wall 320. Two first elastic pieces 352 are also provided, arranged respectively corresponding to the two first fixing pieces 351. The second end of the blocking structure 340 extends between the two first fixing pieces 351. The blocking structure 340 further includes an abutting portion 344 that abuts against each of the first elastic pieces 352. One end of each first elastic piece 352 is fixedly connected to the corresponding first fixing piece 351, and the other end abuts against the corresponding abutting portion 344 of the blocking structure 340. In this embodiment, the first elastic pieces 352 may be compression springs.

When installing the light beads 200 on the light plate 100, the light beads 200 are laid onto the flow guiding assemblies 140. At this time, the main airflow channel 122 is supplied with an airflow. The airflow enters the gas storage space 342 through the first through hole 321, driving the blocking structure 340 to move toward the side facing away from the bottom plate 110, causing the first elastic pieces 352 to undergo compressive deformation and store elastic potential energy. After the light beads 200 are installed, and the airflow supply to the main airflow channel 122 is stopped, the first elastic pieces 352 release the stored potential energy to generate a restoring force, thereby assisting in moving the blocking structure 340 back toward the bottom plate 110. This allows the blocking structure 340 to more rapidly return to its initial state, thereby facilitating the assembly of the light plate 100.

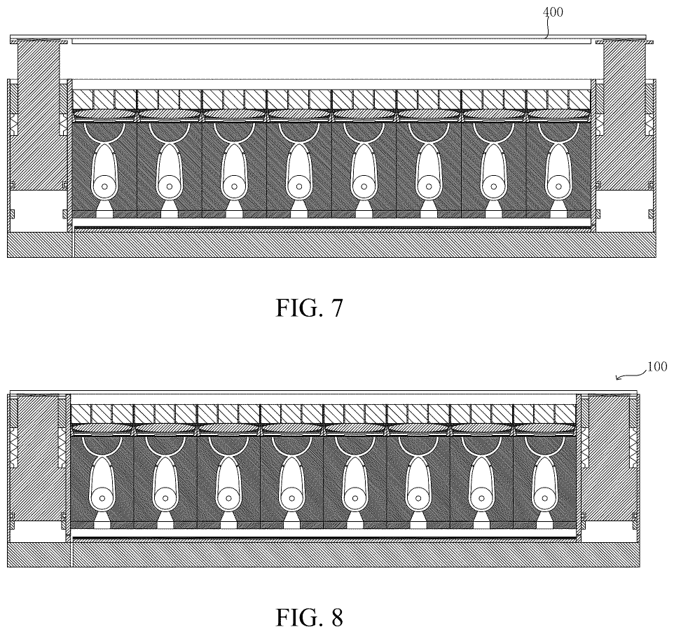

As shown in FIGS. 5 and 6, FIG. 5 is a schematic diagram of a light plate according to the second embodiment of the present application in which light beads are laid prior to installation. FIG. 6 is a schematic diagram of a light plate with all light beads installed according to the second embodiment of the present application. Further, as shown in FIGS. 7 and 8, a glass cover plate 400 is disposed on the light plate 100. The glass cover plate 400 is fixedly attached to the end of the blocking structure 340 facing away from the bottom plate 110 via the suction piece 343. As illustrated in FIG. 7, the glass cover plate 400 is in a state ready for installation. After the installation of the light beads 200 on the light plate 100 is completed and the airflow into the main airflow channel 122 is stopped, the blocking structure 340 moves toward the bottom plate 110. As a result, the glass cover plate 400 is driven to move in the direction of the bottom plate 110, so as to be installed on the side of the light beads 200 facing away from the bottom plate 110, thereby protecting the light beads 200. The final installed state is illustrated in FIG. 8. A transparent protective piece may further be disposed on the side of the glass cover plate 400 facing towards the light beads 200. The transparent protective piece is used to maintain a spacing between the light beads 200 and the glass cover plate 400, in order to prevent the glass cover plate 400 from directly contacting and pressing against the light beads 200 during installation. In this embodiment, the transparent protective piece may be made of transparent rubber, so as to provide a certain degree of elastic deformation capability, thereby preventing compression of the light beads 200. The suction piece 343 may be a suction cup or other adhesive (or vacuum-based, attractive) components to facilitate the suction of the glass cover plate 400.

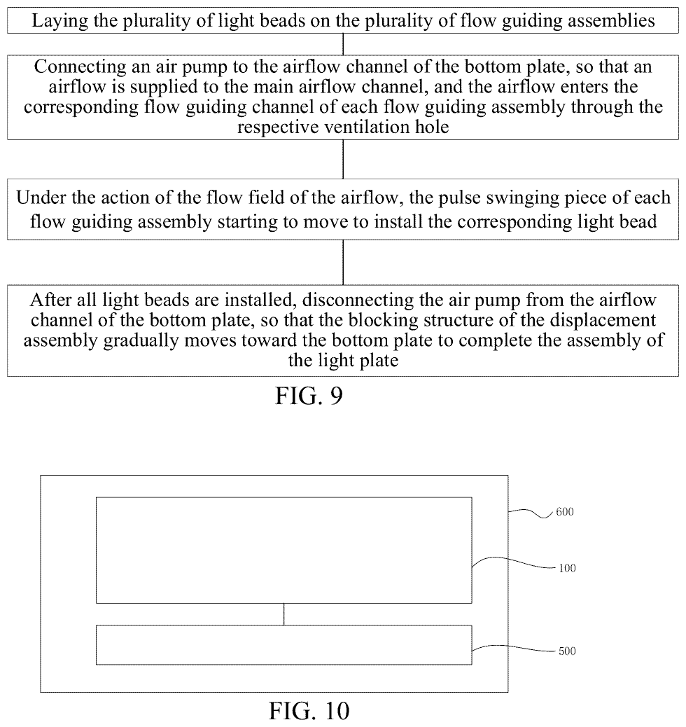

As shown in FIG. 9, as a third embodiment of the present application, a method for assembling a light plate is disclosed. The light plate may be the light plate described in the above embodiments. The method for assembling the light plate includes the following steps:
laying the light beads on the flow guiding assemblies;
connecting an air pump to the airflow channel of the bottom plate, so that an airflow is introduced into the main airflow channel, and the airflow enters the corresponding flow guiding channel of each flow guiding assembly through the respective ventilation hole;
under the action of the flow field of the airflow, the pulse swinging piece of each flow guiding assembly starting to move to install the corresponding light bead;
specifically, when the pulse swinging piece starts to move, the swinging end of the pulse swinging piece alternately contacts the inner walls on both sides of the corresponding first cavity, such that airflow is alternately discharged from the corresponding first branch flow channel and second branch flow channel, generating an airflow pulse force to lift the corresponding light bead on the flow guiding assembly, thereby enabling the light bead to gradually adjust its position on the flow guiding assembly until the corresponding first positioning piece and second positioning piece are engaged together to achieve the installation of the corresponding light bead; and
after all light beads are installed, disconnecting the air pump from the airflow channel of the bottom plate, so that the blocking structure of the displacement assembly gradually moves toward the bottom plate to complete the assembly of the light plate.

Further, in the step “after all the light beads are installed, disconnecting the air pump from the airflow channel of the bottom plate so that the blocking structure of the displacement assembly gradually moves toward the bottom plate to complete the assembly of the light plate”, after the air pump is disconnected from the airflow channel of the bottom plate, the glass cover plate is mounted onto a suction auxiliary mounting piece for suction. The blocking structure of the displacement assembly gradually moves toward the bottom plate, thereby driving the glass cover plate to gradually move along with the blocking structure to a designated position, thus completing the assembly of the light plate.

In the method of assembling the light plate in this embodiment, each corresponding light bead is lifted upward through the structure of the flow guiding channel in each flow guiding assembly, causing the light bead to gradually adjust its position on the flow guiding assembly, thereby realizing the installation of the light bead. Compared with the related installation process of Micro-LED display screens, this method reduces the requirements on the mass transfer process in manufacturing Micro-LED display screens, improving both the installation efficiency and accuracy of the light beads.

As shown in FIG. 10, as a fourth embodiment of this application, a display device 600 is disclosed. The display device 600 includes a driving circuit 500 and the light plate 100 as described in the above embodiments. The driving circuit 500 is used to drive the light plate 100 to emit light. In the display device of this embodiment, the structure of the flow guiding channel in the flow guiding assembly is used to lift the light bead, allowing the light bead to gradually adjust its position on the flow guiding assembly, thereby achieving the installation of the light bead. Compared with the related installation process of Micro-LED display screens, this reduces the requirements on the mass transfer process in manufacturing Micro-LED display screens, thus improving the installation efficiency and accuracy of the light beads.

It should be noted that the limitations of the various steps or operations involved in this solution are not to be interpreted to limit the order of the steps or operations, under the premise of not affecting the implementation of the specific solution. The steps or operations written earlier can be executed first, or later, or even at the same time with the steps or operations written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application.

What is claimed is:

1. A light bead, applied to a light plate and comprising:
a light-emitting chip, disposed at a bottom of the light bead;
a light diffusing and collimating assembly, disposed on a light-exiting side of the light-emitting chip and configured to diffuse and collimate light emitted by the light-emitting chip into parallel rays for emission; and
a light-exiting layer, comprising a first light-emitting region, a second light-emitting region, a third light-emitting region, and two baffles; wherein one of the two baffles is disposed between the first light-emitting region and the second light-emitting region, and the other one of the two baffles is disposed between the second light-emitting region and the third light-emitting region; wherein the first light-emitting region comprises a first color phosphor and a first color film, the second light-emitting region comprises a second color phosphor and a second color film, and the third light-emitting region comprises a transparent film; wherein the light-emitting chip is disposed corresponding to a central portion of the light-exiting layer;
wherein when the light-emitting chip is in operation, the light emitted by the light-emitting chip is operative to pass through the light diffusing and collimating assembly and be emitted into each of the first light-emitting region, the second light-emitting region, and the third light-emitting region, thus forming a first color light after passing through the first light-emitting region, forming a second color light after passing through the second light-emitting region, and not changing a color of the light after passing through the third light-emitting region, and the light bead is operative to emit light in three different colors.

2. The light bead as recited in claim 1, wherein the light diffusing and collimating assembly comprises:
a diffusion plate, disposed adjacent to the light-exiting side of the light-emitting chip;
a convex lens, disposed on a side of the diffusion plate facing away from the light-emitting chip; and
a planarization layer, disposed at an edge region of the convex lens thereby enabling a side of the light diffusing and collimating assembly adjacent to the light-exiting layer to be formed as a flat surface;
wherein when the light-emitting chip is in operation, the light emitted by the light-emitting chip is operative to pass through the diffusion plate to enlarge an emitting angle of the light so that the light is operative to enter various regions of the convex lens; under an action of the convex lens and the planarization layer, the light is corrected to be perpendicular to a light-exiting surface of the light bead and enters the light-exiting layer.

3. The light bead as recited in claim 1, wherein the light emitted by the light-emitting chip is blue light, and wherein the light bead is configured to adopt one of the following two alternative options:
one alternative option being that the first color phosphor is a red phosphor, the first color film is a red color film, the second color film is a green phosphor, and the second color film is a green color film; and
the other alternative option being that the first color phosphor is a green phosphor, the first color film is a green color film, the second color phosphor is a red phosphor, and the second color film is a red color film.

4. The light bead as recited in claim 1, further comprising a reflective layer, which is disposed on a side of the light-emitting chip facing away from the light diffusing and collimating assembly and configured to reflect the light emitted by the light-emitting chip.

5. The light bead as recited in claim 4, further comprising a second positioning piece disposed on a side of the reflective layer facing away from the light-emitting chip, the second positioning piece comprising a magnetic positioning piece.

6. A light plate, applied to a display device and comprising:
a bottom plate, wherein there is disposed an airflow channel on the bottom plate, the airflow channel comprising a plurality of ventilation holes and a main airflow channel in communication with the plurality of ventilation holes;
a partition plate, spaced from the bottom plate and comprising a plurality of sections, wherein a number of the plurality of sections is equal to a number of the plurality of ventilation holes, each of the plurality of sections comprising a respective ventilation hole; wherein the main airflow channel is disposed between the partition plate and the bottom plate, and wherein an airflow is operative to be discharged through the plurality of ventilation holes after entering the main airflow channel;
a plurality of flow guiding assemblies, the plurality of flow guiding assemblies being disposed on the partition plate and disposed on the plurality of sections in one-to-one correspondence; wherein each of the plurality of flow guiding assemblies comprises a flow guiding channel in communication with the respective ventilation hole, the flow guiding channel comprising a first branch flow channel and a second branch flow channel; wherein an air inlet end of the first branch flow channel and an air inlet end of the second branch flow channel are each in communication with the respective ventilation hole, and wherein an air outlet end of the first branch flow channel and an air outlet end of the second branch flow channel are disposed on a side of the corresponding flow guiding assembly facing away from the partition plate and are spaced apart from each other; wherein each of the plurality of flow guiding assemblies comprises a first positioning piece disposed on a side facing away from the partition plate; and
a plurality of light beads, each of which comprising a light-emitting chip, a light diffusing and collimating assembly, and a light-exiting layer; wherein the light-emitting chip is disposed at a bottom of the light bead, the light diffusing and collimating assembly is disposed on a light-exiting side of the light-emitting chip and is configured to diffuse and collimate light emitted by the light-emitting chip into parallel rays for emission; wherein the light-exiting layer comprises a first light-emitting region, a second light-emitting region, a third light-emitting region, and two baffles; wherein one of the two baffles is disposed between the first and second light-emitting regions, and the other one of the two baffles is disposed between the second light-emitting region and the third light-emitting region; wherein the first light-emitting region comprises a first color phosphor and a first color film, the second light-emitting region comprises a second color phosphor and a second color film, and the third light-emitting region comprises a transparent film; wherein the light-emitting chip is disposed corresponding to a central portion of the light-exiting layer; wherein the plurality of light beads are arranged in one-to-one correspondence on the plurality of flow guiding assemblies; wherein each of the plurality of light beads comprises a second positioning piece that is configured to be engaged with the first positioning piece of the corresponding flow guiding assembly, wherein the first positioning piece and the second positioning piece are configured to be engaged with each other to install the light bead onto the corresponding flow guiding assembly;
wherein when the light-emitting chip is in operation, the light emitted by the light-emitting chip is operative to pass through the light diffusing and collimating assembly and be emitted into each of the first light-emitting region, second light-emitting region, and third light-emitting region, thus forming first color light after passing through the first light-emitting region, a second color light after passing through the second light-emitting region, and not changing the color of the light after passing through the third light-emitting region, so that the light bead is operative to emit light in three different colors;
wherein when the plurality of light beads are laid on the plurality of flow guiding assemblies, an airflow is operative to be supplied to the main airflow channel so that the airflow is operative to alternately pass through the first branch flow channel and the second branch flow channel in each flow guiding assembly and be discharged, thereby lifting the corresponding light bead located on each of the plurality of flow guiding assemblies and enabling the light bead to gradually adjust a position thereof on the flow guiding assembly until the corresponding first positioning piece and second positioning piece are engaged with each other thus completing the installation of the light bead.

7. The light plate as recited in claim 6, further comprising a displacement assembly, disposed in an edge region of the bottom plate and comprising:
a first retaining wall and a second retaining wall, wherein the second retaining wall is disposed adjacent to the plurality of flow guiding assemblies, wherein the first retaining wall and the second retaining wall are spaced apart to define an accommodating space, wherein the second retaining wall comprises a first through hole in communication with the main airflow channel to allow the airflow to enter the accommodating space; and
a blocking structure, disposed in the accommodating space and comprising a first end adjacent to the bottom plate and a second end facing away from the bottom plate; wherein the first end of the blocking structure comprises a sealing piece and abuts against the first retaining wall and the second retaining wall to define a gas storage space between the first end of the blocking structure and the bottom plate; wherein the first through hole is in communication with the gas storage space; and wherein the second end of the blocking structure comprises a suction piece configured to suction a glass cover plate in the display device;
wherein when the plurality of light beads are laid on the plurality of flow guiding assemblies and the airflow is supplied to the main airflow channel, the airflow is operative to enter the gas storage space through the first through hole thereby moving the blocking structure away from the bottom plate to prevent the plurality of light beads from jumping out of the light plate.

8. The light plate as recited in claim 7, wherein the displacement assembly further comprises a restoration structure, the restoration structure comprising two first fixing pieces and two first elastic pieces; wherein the two first fixing pieces are disposed on the first retaining wall and the second retaining wall, respectively, and wherein the two first elastic pieces are disposed corresponding to the two first fixing pieces, respectively;
wherein the second end of the blocking structure extends between the two first fixing pieces, and wherein the blocking structure further comprises an abutting portion for abutting each of the two first elastic pieces;
wherein one end of each of the two first elastic pieces is fixedly connected to the corresponding first fixing piece, and another end of the first elastic piece abuts against the corresponding abutting portion of the blocking structure;
wherein when the airflow is supplied to the main airflow channel, the airflow is operative to enter the gas storage space through the first through hole thereby moving the blocking structure away from the bottom plate and causing each of the two first elastic pieces to be compressed and store potential energy; wherein when the supply of the airflow to the main airflow channel is stopped, each of the two first elastic pieces is operative to release the stored potential energy to move the blocking structure toward the bottom plate.

9. The light plate as recited in claim 8, wherein each of the two first elastic pieces comprises a compression spring.

10. The light bead as recited in claim 6, wherein each light-emitting chip is disposed corresponding to a central portion of the respective light-exiting layer.

11. The light bead as recited in claim 5, wherein the magnetic positioning piece comprises an electromagnet.

12. The light plate as recited in claim 6, wherein the first positioning piece and the second positioning piece are each a magnetic piece, and wherein the first positioning piece and the second positioning piece are operative to be magnetically connected to be engaged with each other.

13. The light plate as recited in claim 6, wherein each of the plurality of flow guiding assemblies comprises a main body, a rotating shaft, and a pulse swinging piece; wherein the main body is disposed on the partition plate and comprises a first cavity in communication with the corresponding flow guiding channel; wherein each of the plurality of ventilation holes is in communication with the corresponding flow guiding channel through the corresponding first cavity;
wherein the rotating shaft and the pulse swinging piece are disposed within the first cavity, and wherein the pulse swinging piece comprises a rotating end and a swinging end disposed away from the rotating end, the rotating shaft being rotatably connected to the rotating end;
wherein when the rotating end is rotating, the swinging end is operative to alternately contact inner walls on both sides of the corresponding first cavity according to a rotational direction of the rotating end, so that the airflow is operative to alternately exit from the corresponding first branch flow channel and the corresponding second branch flow channel.

14. The light plate as recited in claim 13, wherein along a light-emitting direction of the light plate, a cross-section of the swinging end of the pulse swinging piece is semicircular, a cross-section of each the first branch flow channel and the second branch flow channel is an arc, and wherein the cross-section of the first branch flow channel and the cross-section of the second branch flow channel is joined to form a semicircular arc shape.

15. The light plate as recited in claim 14, wherein along the light-emitting direction of the light plate, a curvature of the cross-section of the swinging end is greater than a curvature of the cross-section of each of the first branch flow channel and the second branch flow channel.

16. The light plate as recited in claim 13, wherein each of the plurality of flow guiding assemblies further comprises two elastic recovery pieces that are respectively disposed on both sides of the swinging end of the respective pulse swinging piece; wherein one end of each of the two elastic recovery pieces is connected to the swinging end, and another end of the elastic recovery piece is connected to a corresponding inner wall of the first cavity.

17. The light plate as recited in claim 16, wherein each of the two elastic recovery pieces is a return spring, one end of which is connected to the corresponding inner wall of the first cavity, and another end of which is connected to the swinging end of the respective pulse swinging piece.

18. The light plate as recited in claim 6, wherein the bottom plate further comprises a circuit board and an air barrier layer disposed on the circuit board, the circuit board being electrically connected to the plurality of light beads, and the air barrier layer covering the circuit board.

19. The light plate as recited in claim 7, wherein the light plate comprises a glass cover plate, which is fixed by suction to an end of the blocking structure facing away from the bottom plate through the suction piece.

20. A display device, comprising a driving circuit and a light plate; wherein the light plate comprises a bottom plate, a partition plate, a plurality of flow guiding assemblies, and a plurality of light beads;
wherein there is disposed an airflow channel on the bottom plate, the airflow channel comprising a plurality of ventilation holes and a main airflow channel in communication with the plurality of ventilation holes;
wherein the partition plate is spaced apart from the bottom plate and comprises a plurality of sections, wherein a number of the plurality of sections is equal to a number of the plurality of ventilation holes; wherein each of the plurality of sections comprises a respective ventilation hole; wherein the main airflow channel is disposed between the partition plate and the bottom plate; wherein an airflow is operative to be discharged through the plurality of ventilation holes after entering the main airflow channel;
wherein the plurality of flow guiding assemblies are disposed on the partition plate and disposed on the plurality of sections in one-to-one correspondence; wherein each of the plurality flow guiding assemblies comprises a flow guiding channel in communication with the respective ventilation hole, the flow guiding channel comprising a first branch flow channel and a second branch flow channel; wherein an air inlet end of the first branch flow channel and an air inlet end of the second branch flow channel are each in communication with the respective ventilation hole; wherein an air outlet end of the first branch flow channel and an air outlet end of the second branch flow channel are disposed on a side of the corresponding flow guiding assembly facing away from the partition plate and are spaced apart from each other; wherein each of the plurality of flow guiding assemblies comprises a first positioning piece disposed on a side facing away from the partition plate;
wherein each of the plurality of light beads comprises a light-emitting chip, a light diffusing and collimating assembly, and a light-exiting layer; wherein the light-emitting chip is disposed at a bottom of the light bead, the light diffusing and collimating assembly is disposed on a light-exiting side of the light-emitting chip and is configured to diffuse and collimate light emitted by the light-emitting chip into parallel rays for emission;
wherein the light-exiting layer comprises a first light-emitting region, a second light-emitting region, a third light-emitting region, and two baffles; wherein one of the two baffles is disposed between the first light-emitting region and the second light-emitting region, and the other one of the two baffles is disposed between the second light-emitting region and the third light-emitting region; wherein the first light-emitting region comprises a first color phosphor and a first color film, the second light-emitting region comprises a second color phosphor and a second color film, and the third light-emitting region comprises a transparent film;
wherein the light-emitting chip is disposed corresponding to a central portion of the light-exiting layer; wherein the plurality of light beads are disposed in one-to-one correspondence on the plurality of flow guiding assemblies; wherein each of the plurality of light beads comprises a second positioning piece that is configured to be engaged with the corresponding first positioning piece, wherein the first positioning piece and the second positioning piece are configured to be engaged with each other to install each light bead onto the corresponding flow guiding assembly;
wherein when the light-emitting chip is in operation, the light emitted by the light-emitting chip is operative to pass through the light diffusing and collimating assembly and be emitted into each of the first light-emitting region, the second light-emitting region, and the third light-emitting region, thus forming a first color light after passing through the first light-emitting region, a second color light after passing through the second light-emitting region, and not changing the color of the light after passing through the third light-emitting region, so that each light bead is operative to emit light in three different colors;
wherein when the plurality of light beads are arranged on the plurality of flow guiding assemblies, an airflow is operative to be supplied to the main airflow channel so that airflow is operative to alternately pass through the first branch flow channel and the second branch flow channel and be discharged, thereby lifting the corresponding light bead located on each of the flow guiding assemblies and enabling the light bead to gradually adjust a position thereof on the flow guiding assembly until the corresponding first positioning piece and second positioning piece are engaged with each other thus completing the installation of the light bead;
wherein the driving circuit is configured to drive the light plate to emit light.
